(19) United States
(12) Patent Application Publication
(10) Pub. No.: US 2026/0054195 A1
(43) Pub. Date: Feb. 26, 2026

(54) APPARATUS FOR TRAPPING FUMES AND SYSTEM FOR PROCESSING SUBSTRATE USING THE SAME

(71) Applicant: SEMES CO., LTD., Cheonan-si (KR)

(72) Inventors: Jae Oh BANG, Seoul (KR); Eun Ju LEE, Asan-si (KR); Ju Won KIM, Yongin-si (KR); Moon Hyung BAE, Hwaseong-si (KR)

(21) Appl. No.: 19/231,424

(22) Filed: Jun. 7, 2025

(30) Foreign Application Priority Data
Aug. 26, 2024 (KR) 10-2024-0114091

(51) Int. Cl. B01D 8/00; G03F 7/26; H01L 21/67

(52) U.S. Cl. CPC B01D 8/00; G03F 7/26; H01L 21/67017

(57) ABSTRACT

An apparatus for trapping fumes includes a fume trapping unit including a first flow path for an airflow including fumes to move, a first inlet configured to allow the airflow to flow into the first flow path, and a first outlet configured to discharge the airflow from the first flow path; a cooling unit including a second flow path for refrigerant for cooling the airflow to move, a second inlet configured to allow the refrigerant to flow into the second flow path, and a second outlet configured to discharge the refrigerant from the second flow path; and a pressure sensor configured to measure pressure in the first flow path, wherein the cooling unit is disposed to be in surface-contact with one surface of the fume trapping unit.

### CROSS-REFERENCE TO RELATED APPLICATION(S)

This application claims benefit of priority to Korean Patent Application No. 10-2024-0114091 filed on Aug. 26, 2024 in the Korean Intellectual Property Office, the disclosure of which is incorporated herein by reference in its entirety.

### BACKGROUND

### 1. Field

The present disclosure relates to an apparatus for trapping fumes and a system for processing a substrate using the same.

### 2. Description of Related Art

Generally, among semiconductor manufacturing processes, if desired, a substrate may be heat-treated during processes such as photolithography, etching, and packaging and subsequent processes may be performed. For example, among semiconductor manufacturing processes, the photolithography process may include performing photoresist application, development, cleaning, and heat treatment processes on a substrate in a process chamber. For example, in the heat treatment process, the substrate may be heated to a predetermined temperature using a heating means and a bake process may be performed.

In the bake process, fumes such as reaction byproducts or foreign substances may be generated during the heat treatment of a substrate. However, when the fumes generated by heating the substrate flow into another auxiliary device (e.g., a cooling water supply device, vacuum pump, or the like) connected to the bake chamber, atmosphere may be contaminated or process failure may occur.

### SUMMARY

An embodiment of the present disclosure is to provide an apparatus for trapping fumes which may improve fume removal efficiency, and a system for processing a substrate using the same.

An embodiment of the present disclosure is to provide an apparatus for trapping fumes, which may improve cooling performance through a cooling flow path disposed to be in surface-contact with a flow path through which an airflow including fumes moves, and a system for processing a substrate using the same.

An embodiment of the present disclosure is to provide an apparatus for trapping fumes, which may monitor pressure in a flow path through which an airflow including fumes moves and may efficiently perform maintenance of a device, and a system for processing a substrate using the same.

An embodiment of the present disclosure is to provide an apparatus for trapping fumes and a system for processing a substrate using the same may be provided.

According to an embodiment of the present disclosure, an apparatus for trapping fumes includes a fume trapping unit including a first flow path for an airflow including fumes to move, a first inlet configured to allow the airflow to flow into the first flow path, and a first outlet configured to discharge the airflow from the first flow path; a cooling unit including a second flow path for refrigerant for cooling the airflow to move, a second inlet configured to allow the refrigerant to flow into the second flow path, and a second outlet configured to discharge the refrigerant from the second flow path; and a pressure sensor configured to measure pressure in the first flow path, wherein the cooling unit is disposed to be in surface-contact with one surface of the fume trapping unit.

According to an embodiment of the present disclosure, a system for processing a substrate includes an apparatus for trapping fumes including a fume trapping unit, a cooling unit disposed to be surface-contact with one surface of the fume trapping unit, and a pressure sensor configured to measure pressure in the fume trapping unit; and an ejector connected to the apparatus for trapping fumes, wherein the fume trapping unit includes a first flow path for an airflow including fumes to move, a first inlet configured to allow the airflow to flow into the first flow path, and a first outlet configured to discharge the airflow from the first flow path, and wherein the cooling unit includes a second flow path for a refrigerant for cooling the airflow to move, a second inlet configured to allow the refrigerant to flow into the second flow path, and a second outlet configured to discharge the refrigerant from the second flow path. According to an embodiment of the present disclosure,

a system for processing a substrate includes a chamber; a substrate support unit disposed in the chamber and supporting the substrate; an apparatus for trapping fumes including a fume trapping unit disposed on a side of the substrate, a cooling unit disposed to be in surface-contact with one surface of the fume trapping unit, and a pressure sensor configured to measure pressure in the fume trapping unit; and an exhaust line configured to exhaust the chamber and an ejector connected to the apparatus for trapping fumes, wherein the substrate support unit includes a heater plate configured to heat the substrate; one or more vacuum holes formed on the heater plate and configured to adsorb the substrate; and a vacuum line connected to the one or more vacuum holes, wherein the fume trapping unit includes a first flow path for an airflow including fumes to move, a first inlet configured to allow the airflow to flow in from the vacuum line to the first flow path, and a first outlet configured to discharge the airflow from the first flow path, wherein the cooling unit includes a refrigerant supply line, a second flow path configured to move refrigerant for cooling the airflow, a second inlet configured to allow the refrigerant to flow in from the refrigerant supply line to the second flow path, and a second outlet configured to discharge the refrigerant from the second flow path, and wherein the apparatus for trapping fumes is disposed on a side of the substrate support unit, connected to the vacuum line, removes fume included in an airflow flowing in through the vacuum line from the vacuum hole, and exhausts the airflow from which the fume is removed through the exhaust line.

### BRIEF DESCRIPTION OF DRAWINGS

The and other aspects, features, and advantages of the present disclosure will be more clearly understood from the following detailed description, taken in combination with the accompanying drawings, in which:

FIG. 1 is a diagram illustrating a system for processing a substrate according to an embodiment of the present disclosure;

FIG. 2 is a block diagram illustrating a system for processing a substrate according to an embodiment of the present disclosure;

FIG. 3A is a perspective diagram illustrating an upper portion of an apparatus for trapping fumes according to an embodiment of the present disclosure;

FIG. 3B is a perspective diagram illustrating a lower portion of an apparatus for trapping fumes according to an embodiment of the present disclosure;

FIG. 4 is a cross-sectional diagram illustrating a portion of components of an apparatus for trapping fumes according to an embodiment of the present disclosure;

FIG. 5 is an exploded perspective diagram illustrating an apparatus for trapping fumes according to an embodiment of the present disclosure;

FIG. 6 is a graph indicating temperature of an airflow passing through an apparatus for trapping fumes over time according to an embodiment of the present disclosure;

FIG. 7 is a graph indicating temperature of an airflow passing through an apparatus for trapping fumes depending on position in a flow path according to an embodiment of the present disclosure; and

FIG. 8 is a cross-sectional diagram illustrating a portion of components of an apparatus for trapping fumes according to another embodiment of the present disclosure.

### DETAILED DESCRIPTION

Hereinafter, embodiments of the present disclosure will be described as below with reference to the accompanying

### DRAWINGS

The present disclosure is not limited to exemplary embodiments, and it is to be understood that various modifications may be made without departing from the spirit and scope of the present disclosure.

Also, descriptions of functions and constructions that are well known to one of ordinary skill in the art may be omitted for increased clarity and conciseness. In the accompanying drawings, some elements may be

exaggerated, omitted or briefly illustrated, and the sizes of the elements do not necessarily reflect the actual sizes of these elements.

Also, redundant descriptions and detailed descriptions of known functions and elements which may unnecessarily render the gist of the present disclosure obscure will be omitted. The terms described below are defined in consideration of functions thereof in the present disclosure, and may vary depending on the intention or custom of a user or operator. Accordingly, the definitions thereof should be based on the descriptions throughout this specification. Terms used in the present specification are for explaining the embodiments rather than limiting the present invention. Unless explicitly described to the contrary, a singular form includes a plural form in the present specification.

In the drawings, same elements having the same function and operation will be indicated by same reference numerals. The terms such as “upper” “upper portion” “upper surface,” “lower,” “lower portion,” “lower surface,” “side surface,” and the like, are based on the drawing and may actually vary depending on the direction in which the elements or components are arranged.

In the embodiments, the term “connected” may not only refer to “directly connected” but also include “indirectly connected” with another component interposed therebetween. The terms, “include,” “comprise,” “is configured to,” or the like of the description are used to indicate the presence of features, numbers, steps, operations, elements, portions or combination thereof, and do not exclude the possibilities of combination or addition of one or more features, numbers, steps, operations, elements, portions or combination thereof.

It should be noted that embodiments or examples described in this specification is not limited to a single embodiment or example, and may be combined with other embodiments or examples. Accordingly, the patent claims is only an example of an embodiment, and the technical idea of the present disclosure should not be interpreted merely as a combination with the claim, and the combination with various claims is also included in the scope of the technical idea of the present disclosure.

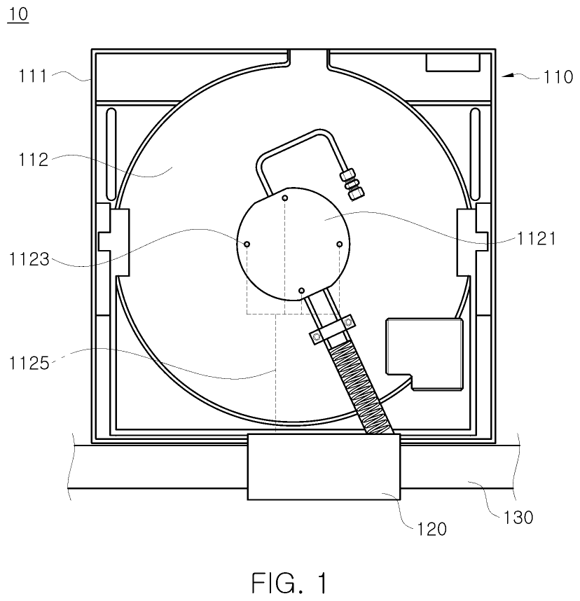

FIG. 1 is a diagram illustrating a system for processing a substrate according to an embodiment.

Referring to FIG. 1, the system 100 for processing a substrate may include a baking unit 110, and an apparatus 120 for trapping fumes and an exhaust unit 130.

The baking unit 110 may perform a heat treatment for the substrate. The baking unit 110 may be for performing a baking process for heat-treating a photoresist applied on the substrate by applying heat energy to the substrate before or after an exposure process in a photolithography spinner device, for example.

As illustrated in FIG. 1, the baking unit 110 may include a chamber 111 and a substrate support unit 112.

The substrate support unit 112 may support the substrate in the chamber 111.

The substrate support unit 112 may include a heater plate 1121, one or more vacuum holes 1123, and a vacuum line 1125.

The heater plate 1121 may apply thermal energy to the substrate. The heater plate 1121 may be heat-treated using a heating means such as a heating wire or a thermoelectric element.

One or more vacuum holes 1123 may be formed in the heater plate 1121. The one or more vacuum holes 1123 may adsorb and fix the substrate by vacuum pressure.

The vacuum line 1125 may be connected to the one or more vacuum holes 1123 and may generate vacuum pressure for the one or more vacuum holes 1123.

The apparatus 120 for trapping fumes may be installed to remove fume generated by heat-treating a substrate in the baking unit 110. Specifically, the apparatus 120 for trapping fumes may remove fume included in an airflow flowing in through the vacuum line 1125 from one or more vacuum holes 1123.

The exhaust unit 130 may discharge the airflow generated in the processing space in the chamber 111 to the outside. The exhaust unit 130 may include an exhaust line exhausting the chamber 111.

For example, the exhaust line of the exhaust unit 130 may be connected to an exhaust duct of the baking unit 110.

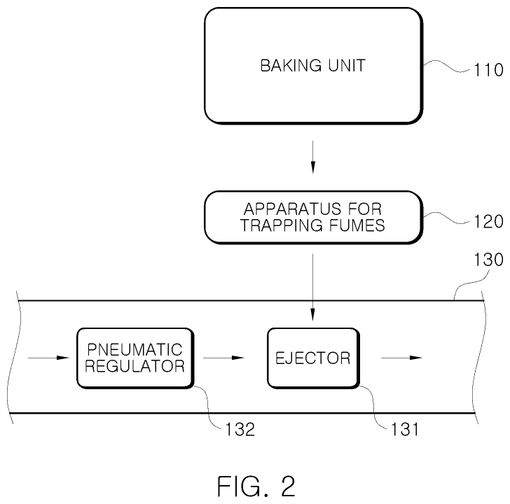

FIG. 2 is a block diagram illustrating a system for processing a substrate according to an embodiment.

Referring to FIG. 2, the exhaust unit 130 may include an ejector 131 and a pneumatic regulator 132.

The ejector 131 may be connected to the apparatus 120 for trapping fumes. The ejector 131 may receive the airflow from which fume is removed from the apparatus 120 for trapping fumes.

The pneumatic regulator 132 may control pressure in the exhaust unit 130. Specifically, the pneumatic regulator 132 may control a flow rate or a velocity of a main airflow exhausted through the exhaust line.

The ejector 131 may exhaust the airflow from which fume is removed, transferred from the apparatus 120 for trapping fumes and a main airflow of the exhaust unit 130 supplied through the pneumatic regulator 132.

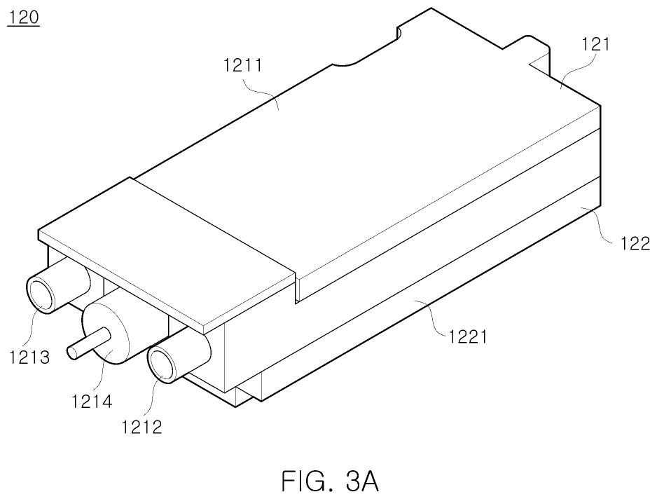

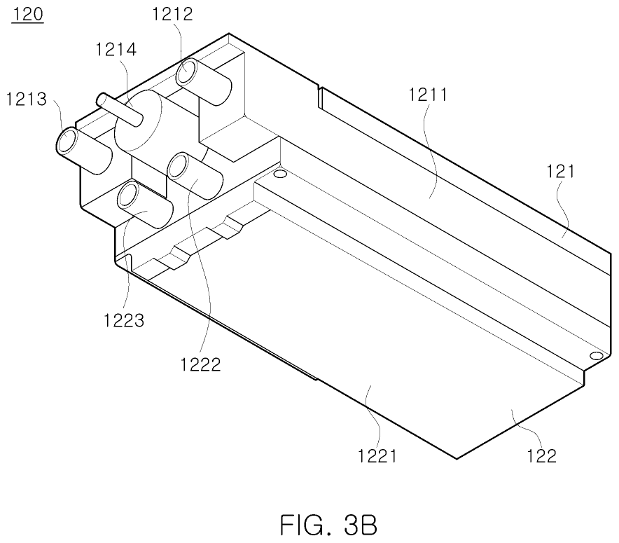

Hereinafter, the apparatus 120 for trapping fumes may be described in detail with reference to FIGS. 3A to 5.

The apparatus 120 for trapping fumes may be disposed, for example, on a front panel of the baking unit 110. The apparatus 120 for trapping fumes may be disposed on the side of the substrate support unit 112.

The apparatus 120 for trapping fumes may be connected to a vacuum line 1125 and may be installed to remove fume included in the airflow flowing in through the vacuum line 1125 from one or more vacuum holes 1123. The apparatus 120 for trapping fumes may exhaust the airflow from which fume is removed through the exhaust unit 130.

The apparatus 120 for trapping fumes may include a fume trapping unit 121 and a cooling unit 122. The fume trapping unit 121 and the cooling unit 122 may be configured to be attached and detached.

The apparatus 120 for trapping fumes may have a structure in which the fume trapping unit 121 and the cooling unit 122 are in surface-contact with each other. The apparatus 120 for trapping fumes may be disposed such that the cooling unit 122 may be in surface-contact with one surface of the fume trapping unit 121, such that the airflow flowing into the fume trapping unit 121 or the fume trapping unit 121 may be effectively cooled.

The apparatus 120 for trapping fumes may have a structure in which the fume trapping unit 121 and the cooling unit 122 are in surface-contact with each other, thereby improving the airflow cooling performance and consequently increasing fume removal efficiency.

The fume trapping unit 121 may include a trap body 1211, a first inlet 1212, and a first outlet 1213.

The first inlet 1212 may be installed such that one end may be connected to the trap body 1211, and may provide a passage for allowing the airflow to flow into the trap body 1211.

The first outlet 1213 may be installed such that one end may be connected to the trap body 1211, and may provide a passage for allowing the airflow to flow out from the trap body 1211.

The first outlet 1213 may be connected to, for example, an ejector 131 of the exhaust unit 130. The ejector 131 may receive the fume-removed airflow flowing out from the first outlet 1213.

The first inlet 1212 and the first outlet 1213 may be disposed to extend in the first direction to one side surface of the fume trapping unit 121. That is, the first inlet 1212 and the first outlet 1213 may be disposed to extend in the same direction on the same surface of the trap body 1211.

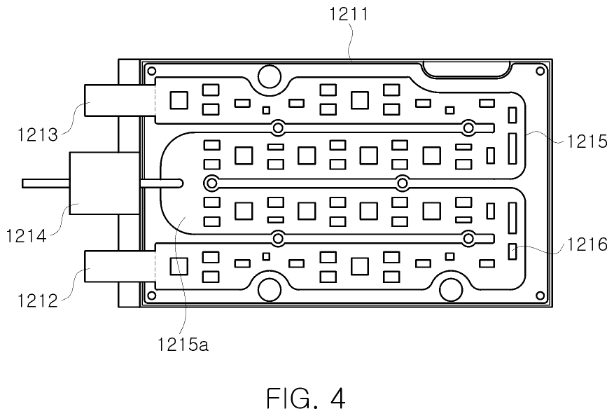

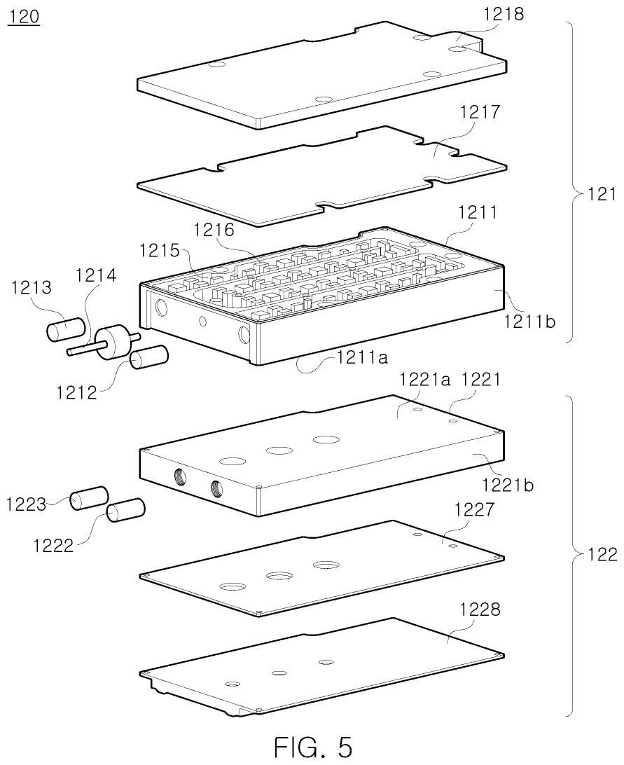

Referring to FIGS. 4 and 5, a first flow path 1215 may be formed in the trap body 1211. Specifically, the trap body 1211 may include a lower-surface portion 1211a and a first side-surface portion 1211b. The first side-surface portion 1211b may include a sidewall extending upwardly from the lower-surface portion 1211a, and may form the first flow path 1215 by a sidewall of the first side-surface portion 1211b.

The first flow path 1215 may provide a passage for the airflow including fumes to move in the trap body 1211.

One end of the first flow path 1215 may be connected to the first inlet 1212, and the other end of the first flow path 1215 may be connected to the first outlet 1213.

That is, the airflow including fumes may move to the first flow path 1215 through the first inlet 1212, and may pass through the first flow path 1215, and may move externally of the apparatus 120 for trapping fumes through the first outlet 1213.

In an embodiment, the first flow path 1215 may have a zigzag shape in which the direction of movement of the airflow changes multiple times in the trap body 1211.

The shape of the first flow path 1215 illustrated in FIGS. 4 and 5 may be exemplary, and the first flow path 1215 may have a flow path shape in which the airflow can move from the first inlet 1212 to the first outlet 1213 in the trap body 1211.

A plurality of resistors 1216 may be formed in the first flow path 1215. The plurality of resistors 1216 may be a structure for dispersing the airflow moving in the first flow path 1215 and capturing fume included in the airflow.

The plurality of resistors 1216 may be installed to partially block the movement of the airflow in the first flow path 1215. For example, the plurality of resistors 1216 may include a plurality of irregular columnar bodies extending upwardly from the lower-surface portion 1211a of the trap body 1211.

The fume trapping unit 121 may include a pressure sensor 1214 configured to measure pressure in the first flow path 1215. The first flow path 1215 may include a buffer region 1215a in which a plurality of resistors 1216 are not formed as illustrated in FIG. 4.

Although the buffer region 1215a may be positioned in a central portion of the first flow path 1215 in FIG. 4, but the buffer region 1215a may be positioned in the other portion of the first flow path 1215. For example, the buffer region 1215a may be positioned in a portion of the first flow path 1215 connected to the first outlet 1213. The pressure sensor 1214 may measure pressure in the buffer region 1215a. The pressure sensor 1214 may monitor changes in pressure due to fume in the first flow path 1215.

As illustrated in FIG. 5, the fume trapping unit 121 may further include a trap cover portions 1217 and 1218 disposed in an upper portion of the trap body 1211. The trap body 1211 may be sealed by the trap cover portions 1217 and 1218.

The trap cover portions 1217 and 1218 may include a first trap cover 1217 and a second trap cover 1218.

The first trap cover 1217 may cover an upper portion of the trap body 1211.

The second trap cover 1218 may be disposed on the upper side of the first trap cover 1217, and may be fixed to and installed in the trap body 1211 with the first trap cover 1217 therebetween.

For example, the second trap cover 1218 may be fixed by being coupled to the trap body 1211 through a fixing member.

The first trap cover 1217 and the second trap cover 1218 may be formed of different materials. The first trap cover 1217 and the second trap cover 1218 may be formed of materials having different properties. Accordingly, the sealing force sealing the trap body 1211 by the trap cover portions 121

For example, the first trap cover 1217 may be manufactured from a material including a resin, and the second trap cover 1218 may be manufactured from a material including a metal.

The plurality of resistors 1216 may include a plurality of irregular columnar bodies extending from the lower-surface portion 1211a to a level at which the first trap cover 1217 is installed.

The cooling unit 122 may cool an internal region the fume trapping unit 121 or the airflow flowing into the fume trapping unit 121. The airflow flowing into the fume trapping unit 121 may have a relatively high temperature, for example, 120-180° C.

The cooling unit 122 may include a cooling body 1221, a second inlet 1222, and a second outlet 1223.

The second inlet 1222 may be installed such that one end may be connected to the cooling body 1221, and may provide a passage for allowing refrigerant to flow into the cooling body 1221.

The second outlet 1223 may be installed such that one end may be connected to the cooling body 1221, and may provide a passage for allowing the airflow to flow out from the cooling body 1221.

The second inlet 1222 and the second outlet 1223 may be disposed on one side surface of the cooling unit 122 to extend in the first direction. That is, the second inlet 1222 and the second outlet 1223 may be disposed on the same surface of the cooling body 1221 to extend in the same direction.

Also, one side surface of the cooling body 1221 on which the second inlet 1222 and the second outlet 1223 are connected to each other may be disposed parallel to one side surface of the trap body 1211 on which the first inlet 1212 and the first outlet 1213 are connected to each other.

That is, the first inlet 1212 and the first outlet 1213 through which the airflow flows in or out and the second inlet 1222 and the second outlet 1223 through which refrigerant flows in or out may be disposed to extend in the same direction.

A second flow path for the refrigerant to move may be formed in the cooling body 1221, similarly to the first flow path 1215.

Specifically, the cooling body 1221 may include an upper-surface portion 1221a and a second side-surface portion 1221b. The second side-surface portion 1221b may include a sidewall extending downwardly from the upper-surface portion 1221a, and may form a second flow path 1225 by a sidewall of the second side-surface portion 1221b.

An upper surface of the upper-surface portion 1221a of the cooling body 1221 may be disposed to be in surface-contact with a lower surface of the lower-surface portion 1211a of the trap body 1211.

The second flow path formed in the cooling body 1221 may provide a passage for refrigerant for cooling the airflow in the cooling body 1221 to move. One end of the second flow path may be connected to the second inlet 1222, and the other end of the second flow path may be connected to the second outlet 1223.

That is, the refrigerant for cooling the airflow may move to the second flow path through the second inlet 1222, may pass through the second flow path, and may move externally of the apparatus 120 for trapping fumes through the second outlet.

In an embodiment, the second flow path may have a shape corresponding to a shape of the first flow path 1215. For example, the second flow path may have a zigzag shape such that the moving direction of the refrigerant in the cooling body 1221 may be the same as the moving direction of the airflow by the first flow path 1215.

Since the fume trapping unit 121 and the cooling unit 122 are disposed to be in surface-contact with each other, cooling performance for cooling the fume trapping unit 121 may be improved.

Also, by disposing the flow path through which the airflow moves in the fume trapping unit 121 and the flow path through which the refrigerant moves in the cooling unit 122 in shapes corresponding to each other, cooling performance may be further improved.

As illustrated in FIG. 5, the cooling unit 122 may further include cooling cover portions 1227 and 1228 disposed in a lower portion of the cooling body 1221. The cooling body 1221 may be sealed by the cooling cover portions 1227 and 1228.

The cooling cover portions 1227 and 1228 may include a first cooling cover 1227 and a second cooling cover 1228.

The first cooling cover 1227 may cover a lower portion of the cooling body 1221.

The second cooling cover 1228 may be disposed on the upper side of the first cooling cover 1227, and may be fixed to and installed in below the cooling body 1221 with the first cooling cover 1227 interposed therebetween.

For example, the second cooling cover 1228 may be fixed by being coupled to the cooling body 1221 through a fixing member.

The first cooling cover 1227 and the second cooling cover 1228 may be formed of different materials. The first cooling cover 1227 and the second cooling cover 1228 may be formed of materials having different properties. Accordingly, sealing force which seals the cooling body 1221 by the cooling cover portions 1227 and 1228 may be improved.

For example, the first cooling cover 1227 may be manufactured from a material including a resin, and the second cooling cover 1228 may be manufactured from a material including a metal.

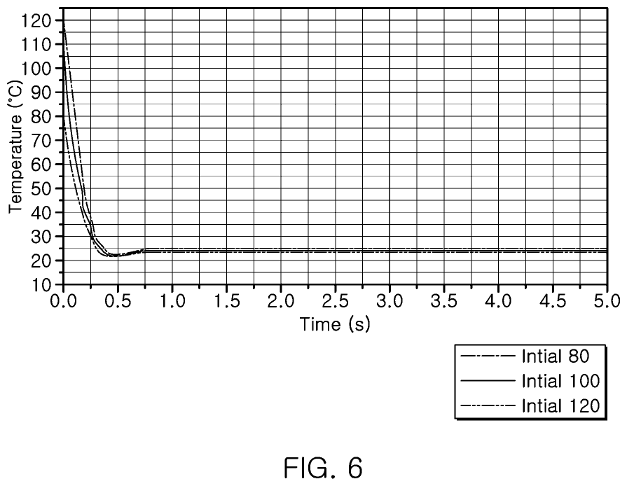

FIG. 6 is a graph indicating temperature of the airflow passing through an apparatus for trapping fumes over time according to an embodiment.

As illustrated in FIG. 6, when an initial temperature of the airflow flowing into the apparatus for trapping fumes is 80° C., 100° C., or 120° C., it was confirmed that the airflow was cooled at a rapid rate while flowing into the apparatus for trapping fumes and moving through the first flow path.

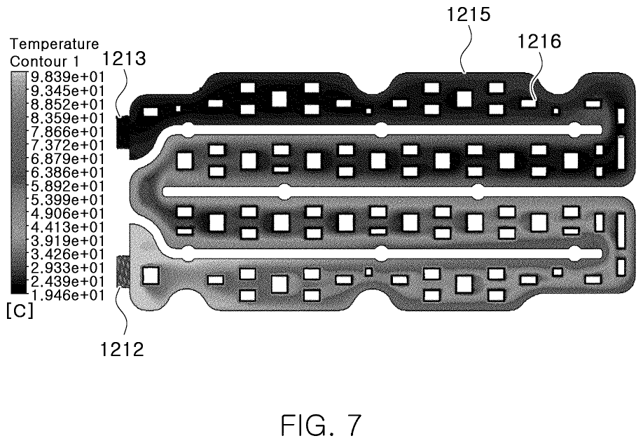

FIG. 7 is a graph indicating temperature of the airflow passing through an apparatus for trapping fumes depending on position in a flow path according to an embodiment.

As illustrated in FIG. 7, it was confirmed that the temperature of the airflow flowing in from the first inlet 1212 gradually decreased while moving toward the first outlet 1213 through the first flow path 1215.

Also, using the apparatus for trapping fumes according to an embodiment, fume included in the airflow may be effectively removed by the plurality of resistors 1216 formed in the first flow path 1215 while the airflow moves through the first flow path 1215.

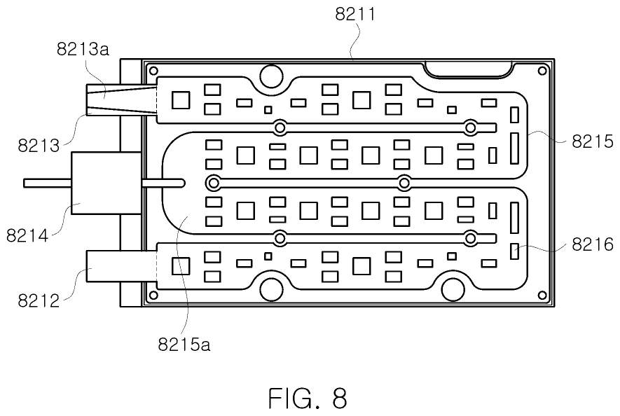

FIG. 8 is a cross-sectional diagram illustrating a portion of components of an apparatus for trapping fumes according to another embodiment. Hereinafter, a detailed description of the components the same as those in the embodiments described with reference to FIGS. 1 to 7 may not be provided.

FIG. 8 may be a cross-sectional diagram illustrating a portion of components of the apparatus for trapping fumes, including a flow path 8215 through which the airflow including fumes moves, an inlet 8212 for allowing the airflow to flow into the flow path 8215, an outlet 8213 for allowing the airflow to flow out of the flow path 8215, and a plurality of resistors 8216 formed in the flow path 8215.

The outlet 8213 may include a gradient member 8213a of which a diameter decreases in a direction away from the flow path 8215.

By including the gradient member 8213a, the outlet 8213 may prevent fume not captured by the plurality of resistors 8216 formed in the flow path 8215 from sticking to the outlet 8213.

In some embodiments provided in the present application, it should be understood that the disclosed device and method may be implemented in other manners. For example, the embodiment of the device described above are merely example, for example, division of the units is merely a logical functional division, and in actual implementation, other division methods may be present, for example, a plurality of units or assemblies may be combined or integrated into another system, or some features may be ignored or not performed. On the other hand, the coupling or direct coupling or communication connection between elements indicated or discussed may be indirect coupling or communication connection through some interface, device or unit, and may be electrical, mechanical or may have other forms.

The units described above as separate components may be physically separate, and the components indicated as units may or may not be physical units, and may be thus disposed in one position or distributed in a plurality of network units. Depending on actual needs, a portion or the entirety of the units may be selected and the purpose of the solution of the present embodiment may be implemented.

That is, each functional unit in each embodiment may be integrated into a processing unit, each unit may be present alone, or two or more units may be integrated into one unit.

According to the aforementioned embodiments, an apparatus for trapping fumes which may improve fume removal efficiency, and a system for processing a substrate using the same may be provided.

Also, an apparatus for trapping fumes, which may improve cooling performance through a cooling flow path disposed to be in surface-contact with a flow path through which the airflow including fumes moves, and a system for processing a substrate using the same may be provided.

Also, an apparatus for trapping fumes, which may monitor pressure in a flow path through which the airflow including fumes moves and may efficiently perform maintenance of a device, and a system for processing a substrate using the same may be provided.

While the embodiments have been illustrated and described above, it will be configured as apparent to those skilled in the art that modifications and variations could be made without departing from the scope of the present disclosure as defined by the appended claims.

What is claimed is:

1. An apparatus for trapping fumes, the apparatus comprising:
a fume trapping unit including a first flow path for an airflow including fumes to move, a first inlet configured to allow the airflow to flow into the first flow path, and a first outlet configured to discharge the airflow from the first flow path;
a cooling unit including a second flow path for refrigerant for cooling the airflow to move, a second inlet configured to allow the refrigerant to flow into the second flow path, and a second outlet configured to discharge the refrigerant from the second flow path; and
a pressure sensor configured to measure pressure in the first flow path,
wherein the cooling unit is disposed to be in surface-contact with one surface of the fume trapping unit.

2. The apparatus of claim 1,
wherein the first flow path has a zigzag shape in which a direction of movement of the airflow changes multiple times, and
wherein a plurality of: resistors configured to disperse the airflow and to capture the fume are formed in the first flow path.

3. The apparatus of claim 2,
wherein the fume trapping unit includes:
a trap body including a lower-surface portion and a first side-surface portion extending upwardly from the lower-surface portion and forming the first flow path; and
a trap cover portion disposed in an upper portion of the trap body, and
wherein the plurality of resistors include a plurality of irregular columnar bodies extending from the lower-surface portion to a level at which the trap cover portion is installed.

4. The apparatus of claim 3,
wherein the trap cover portion includes:
a first trap cover covering an upper portion of the trap body; and
a second trap cover disposed on an upper side of the first trap cover and fixed by being coupled to the trap body with the first trap cover interposed therebetween through a fixing member, and
wherein the first trap cover and the second trap cover are formed of different materials.

5. The apparatus of claim 3,
wherein the cooling unit includes:
a cooling body including an upper-surface portion in surface-contact with the lower-surface portion and a second side-surface portion extending downwardly from the upper-surface portion and forming the second flow path; and
a cooling cover portion disposed in a lower portion of the cooling body,
wherein the second flow path has a shape corresponding to a shape of the first flow path.

6. The apparatus of claim 5,
wherein the cooling cover portion includes:
a first cooling cover for covering a lower portion of the cooling body; and
a second cooling cover disposed on a lower side of the first cooling cover and fixed by being coupled to the cooling body with the first cooling cover interposed therebetween through a fixing member, and
wherein the first cooling cover and the second cooling cover are formed of different materials.

7. The apparatus of claim 2,
wherein the first flow path includes a buffer region in which the plurality of resistors are not formed, and
wherein the pressure sensor measures pressure in the buffer region.

8. The apparatus of claim 3,
wherein the first inlet and the first outlet are disposed on one side surface of the fume trapping unit to extend in a first direction, and
wherein the second inlet and the second outlet are disposed on one side surface of the cooling unit to extend in the first direction, the cooling unit disposed parallel to one side surface of the fume trap.

9. The apparatus of claim 8, wherein the first outlet includes a gradient member of which a diameter decreases in a direction away from the first flow path.

10. A system for processing a substrate, the system comprising:
an apparatus for trapping fumes including a fume trapping unit, a cooling unit disposed to be surface-contact with one surface of the fume trapping unit, and a pressure sensor configured to measure pressure in the fume trapping unit; and
an ejector connected to the apparatus for trapping fumes,
wherein the fume trapping unit includes a first flow path for an airflow including fumes to move, a first inlet configured to allow the airflow to flow into the first flow path, and a first outlet configured to discharge the airflow from the first flow path, and
wherein the cooling unit includes a second flow path for a refrigerant for cooling the airflow to move, a second inlet configured to allow the refrigerant to flow into the second flow path, and a second outlet configured to discharge the refrigerant from the second flow path.

11. The system of claim 10, further comprising:
a pneumatic regulator configured to control pressure in the exhaust unit,
wherein the ejector is connected to the first outlet, and
wherein the ejector exhausts an airflow from the first outlet and a main airflow of the exhaust unit supplied through the pneumatic regulator.

12. The system of claim 10, further comprising:
a substrate support unit supporting a substrate;
one or more vacuum holes formed in the substrate support unit and configured to adsorb the substrate; and
a vacuum line connected to the one or more vacuum holes,
wherein the apparatus for trapping fumes is disposed on a side of the substrate support unit, connected to the vacuum line, removes fume included in an airflow flowing in through the vacuum line from the vacuum hole, and exhausts the airflow from which the fume is removed through the exhaust unit.

13. The system of claim 10,
wherein the first flow path has a zigzag shape in which a direction of movement of the airflow changes multiple times, and
wherein a plurality of resistors configured to disperse the airflow and to capture the fume are formed in the first flow path.

14. The system of claim 13,
wherein the fume trapping unit includes:
a trap body including a lower-surface portion and a first side-surface portion extending upwardly from the lower-surface portion and forming the first flow path; and
a trap cover portion disposed in an upper portion of the trap body,
wherein the plurality of resistors include a plurality of irregular columnar bodies extending from the lower-surface portion to a level at which the trap cover portion is installed.

15. The system of claim 13,
wherein the cooling unit includes:
a cooling body including an upper-surface portion in surface-contact with a lower surface of the fume trapping unit and a second side-surface portion extending downwardly from the upper-surface portion and forming the second flow path; and
a cooling cover portion disposed in a lower portion of the cooling body, and
wherein the second flow path has a shape corresponding to a shape of the first flow path.

16. The system of claim 13,
wherein the first flow path includes a buffer region in which the plurality of resistors are not formed, and wherein the pressure sensor measures pressure in the buffer region.

17. The system of claim 14,
wherein the first inlet and the first outlet are disposed on one side surface of the fume trapping unit to extend in a first direction, and
wherein the second inlet and the second outlet are disposed on one side surface of the cooling unit to extend in the first direction, the cooling unit disposed parallel to one side surface of the fume trap.

18. The system of claim 17, wherein the first outlet includes a gradient member of which a diameter decreases in a direction away from the first flow path.

19. A system for processing a substrate, the system comprising:
a chamber;
a substrate support unit disposed in the chamber and supporting the substrate;
an apparatus for trapping fumes including a fume trapping unit disposed on a side of the substrate, a cooling unit disposed to be in surface-contact with one surface of the fume trapping unit, and a pressure sensor configured to measure pressure in the fume trapping unit; and
an exhaust line configured to exhaust the chamber and an ejector connected to the apparatus for trapping fumes, wherein the substrate support unit includes:
a heater plate configured to heat the substrate;
one or more vacuum holes formed on the heater plate and configured to adsorb the substrate; and
a vacuum line connected to the one or more vacuum holes,
wherein the fume trapping unit includes a first flow path for an airflow including fumes to move, a first inlet configured to allow the airflow to flow in from the vacuum line to the first flow path, and a first outlet configured to discharge the airflow from the first flow path,
wherein the cooling unit includes a refrigerant supply line, a second flow path configured to move refrigerant for cooling the airflow, a second inlet configured to allow the refrigerant to flow in from the refrigerant supply line to the second flow path, and a second outlet configured to discharge the refrigerant from the second flow path, and
wherein the apparatus for trapping fumes is disposed on a side of the substrate support unit, connected to the vacuum line, removes fume included in an airflow flowing in through the vacuum line from the vacuum hole, and exhausts the airflow from which the fume is removed through the exhaust line.

20. The system of claim 19,
wherein a plurality of resistors configured to disperse the airflow and to capture the fume are formed in the first flow path,
wherein the first flow path includes a buffer region in which the plurality of resistors are not formed, and
wherein the pressure sensor measures pressure of the buffer region.
